(19) United States
(12) Patent Application Publication
(10) Pub. No.: US 2023/0422532 A1
(43) Pub. Date: Dec. 28, 2023

(54) ARTIFICIAL INDOOR PHOTOVOLTAIC CELL AND MANUFACTURING METHOD THEREOF

(71) Applicant: KOREA UNIVERSITY RESEARCH AND BUSINESS FOUNDATION, Seoul (KR)

(72) Inventors: Jae Won SHIM, Seoul (KR); Tae Hyuk KIM, Seoul (KR)

(73) Assignee: KOREA UNIVERSITY RESEARCH AND BUSINESS FOUNDATION, Seoul (KR)

(21) Appl. No.: 18/333,027

(22) Filed: Jun. 12, 2023

(30) Foreign Application Priority Data
Jun. 22, 2022 (KR) 10-2022-0076333

(51) Int. Cl. H10K 30/50; H10K 30/20; H10K 30/85; H10K 30/83

(52) U.S. Cl. CPC H10K 30/50; H10K 30/20; H10K 30/85; H10K 30/83; H10K 71/60

(57) ABSTRACT

An artificial indoor photovoltaic cell and a manufacturing method thereof are disclosed. The artificial indoor photovoltaic cell includes: a transparent electrode; an electron transport layer formed on the transparent electrode layer; a photoactive layer formed on the electron transport layer and including a donor layer and an acceptor layer that generate an exciton by indoor light and separate the exciton into positive and negative charges; and a charge transport layer formed on the photoactive layer and made of a material homogenous with the donor layer.

### CROSS-REFERENCE TO RELATED APPLICATION

This application claims under 35 U.S.C. § 119(a) the benefit of Korean Patent Application No. 10-2022-0076333 filed on Jun. 22, 2022, the disclosure of which is incorporated herein by reference in its entirety.

### BACKGROUND

### (a) Technical Field

The present invention relates to an artificial indoor photovoltaic cell and a manufacturing method thereof.

### (b) Background Art

A charge transport layer of an artificial indoor photovoltaic cell should have excellent optical properties and be able to move charge mobility and free charge in a desired direction. In particular, defects present at an interface between an organic semiconductor layer and an electrode are factors that cause recombination during the movement of free charges and impair photovoltaic cell performance.

As the conventional method of designing a charge transport layer, the charge transport layer is formed by a solution process and a thermal evaporation method, which have disadvantages that are not practical in terms of surface planarization, high-temperature process, process time, and cost.

Therefore, a new manufacturing method of inducing efficient energy level alignment inside a photovoltaic cell and reducing interfacial defects is required.

### SUMMARY OF THE INVENTION

The present invention provides an artificial indoor photovoltaic cell and a manufacturing method thereof.

In addition, the present invention provides an artificial indoor photovoltaic cell having improved performance in a low-illumination indoor environment in which power-conversion efficiency (PCE) increases by 25% or more by forming a hole transport layer with a homogeneous material used for an organic semiconductor layer through a transfer lamination technique to greatly suppress defect density and maximize quasi-Fermi level splitting, and a manufacturing method thereof.

In addition, the present invention provides an artificial indoor photovoltaic cell capable of forming a uniform charge transport layer without damage to a lower layer due to surface planarization and heat treatment by using a flat silicon-based organic polymer, and a manufacturing method thereof.

Further, the present invention provides an artificial indoor photovoltaic cell having excellent performance in a low-illumination indoor environment because a filling rate and an open circuit voltage are improved by forming a hole transport layer with a homogeneous material used for an organic semiconductor layer, and a manufacturing method thereof.

An aspect of the present invention provides an artificial indoor photovoltaic cell capable of forming a hole transport layer with a homogeneous material used for an organic semiconductor layer through a transfer lamination technique.

According to an embodiment of the present invention, an artificial indoor photovoltaic cell may include: a transparent electrode; an electron transport layer formed on the transparent electrode layer; a photoactive layer formed on the electron transport layer and including a donor layer and an acceptor layer that generate an exciton by indoor light and separate the exciton into positive and negative charges; and a charge transport layer formed on the photoactive layer and made of a material homogenous with the donor layer.

The charge transport layer may be formed by a lamination technique of forming a coating layer on one surface of a silicon-based organic polymer (PDMS) using a material homogeneous with the donor layer through a solution process method, and transferring the coating layer onto the photoactive layer.

The donor layer and the charge transport layer may be made of any one polymer material among PTQ10, PM6 (PBDB-T-2F), PM7 (PBDB-T-2Cl), PEDOT, and fluorobenzotriazole (FTAZ), respectively.

The charge transport layer may be formed to have a thickness of 1 to 8 nm or less.

According to another aspect of the present invention, there is provided a method of manufacturing an artificial indoor photovoltaic cell capable of forming a hole transport layer with a homogeneous material used for an organic semiconductor layer through a transfer lamination technique.

According to an embodiment of the present invention, a method of manufacturing an artificial indoor photovoltaic cell may include: forming an electron transport layer on a transparent electrode layer; forming a photoactive layer including a donor layer and an acceptor layer, which generate an exciton by indoor light and separate the exciton into positive and negative charges, on the electron transport layer; and forming a charge transport layer made of a homogeneous material as the donor layer on the photoactive layer.

The forming of the charge transport layer may include: forming a coating layer by coating one surface of a silicon-based organic polymer (PDMS) with a material homogeneous with the donor layer; and forming the charge transport layer on the photoactive layer by a lamination technique of disposing the coating layer on an upper surface of the photoactive layer and then transferring the coating layer onto the photoactive layer.

According to an artificial indoor photovoltaic cell and a manufacturing method thereof according to an embodiment of the present invention, it is possible to manufacture an artificial indoor photovoltaic cell having improved performance in a low-illumination indoor environment in which power-conversion efficiency (PCE) increases by 25% or more by forming a hole transport layer with a homogeneous material used for an organic semiconductor layer through a transfer lamination technique to greatly suppress defect density and maximize quasi-Fermi level splitting.

In addition, according to the present invention, by using a flat silicon-based organic polymer, it is possible to form a uniform charge transport layer without damage to a lower layer due to surface planarization and heat treatment.

In addition, according to the present invention, by forming a hole transport layer with a homogeneous material used in an organic semiconductor layer, it is possible to exhibit excellent performance in a low-light indoor environment because a filling rate and an open circuit voltage are improved.

### BRIEF DESCRIPTION OF THE DRAWINGS

FIG. 1 is a diagram showing a detailed structure of an artificial indoor photovoltaic cell according to an embodiment of the present invention.

FIGS. 2A and 2B are process diagrams showing a method of manufacturing artificial indoor photovoltaic cells according to an embodiment of the present invention.

FIG. 3 is a diagram for describing a change in absorption spectra and a chemical structure of artificial indoor photovoltaic cells according to the related art and an embodiment of the present invention.

FIG. 4 is a diagram showing a change in a thickness of a photoactive layer and a 3D AFM profile of the artificial indoor photovoltaic cell according to the related art and an embodiment of the present invention.

FIG. 5 is a diagram showing a comparison result of J-V characteristics and EQE spectra of the artificial indoor photovoltaic cell according to the related art and an embodiment of the present invention.

FIG. 6 is a diagram for describing photovoltaic cell performance according to a thickness according to an embodiment of the present invention.

FIG. 7 is a comparison diagram of slope values for J_{light}-V_{eff} dependence, a Nyquist plot, a J-V curve, and VOC dependence for In(I_{light}) of the artificial indoor photovoltaic cell according to the related art and an embodiment of the present invention.

FIG. 8 is a diagram showing 2D AFM grain-count of the artificial indoor photovoltaic cell according to the related art and an embodiment of the present invention.

FIG. 9 is a comparison diagram of a complex refractive index of a photoactive layer according to the related art and an embodiment of the present invention.

FIG. 10 is a diagram showing a power absorption rate of the artificial indoor photovoltaic cell according to the related art and an embodiment of the present invention.

FIG. 11 is a diagram showing a comparison result of performance in indoor lighting of the artificial indoor photovoltaic cell according to the related art and an embodiment of the present invention.

FIG. 12 is a diagram showing a comparison result of ambient safety of the artificial indoor photovoltaic cell according to the related art and the embodiment of the present invention.

FIG. 13 is a diagram showing performance and EQE spectrum of an FTAZ-based artificial indoor photovoltaic cell according to an embodiment of the present invention.

### DETAILED DESCRIPTION

In the present specification, singular forms include plural forms unless the context clearly indicates otherwise. In the specification, it is to be noted that the terms “comprising” or “including,” and the like are not construed as necessarily including several components or several steps described in the specification and some of the above components or steps may not be included or additional components or steps are construed as being further included. In addition, terms “. . . unit,” “module,” and the like, described in the specification refer to a processing unit of at least one function or operation and may be implemented by hardware or software or a combination of hardware and software.

Hereinafter, exemplary embodiments of the present invention will be described in detail with reference to the accompanying drawings.

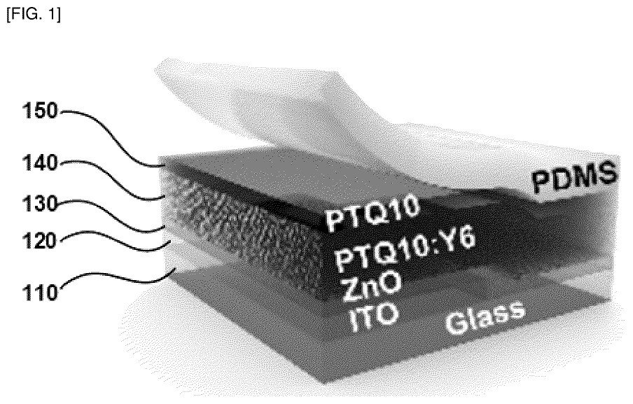

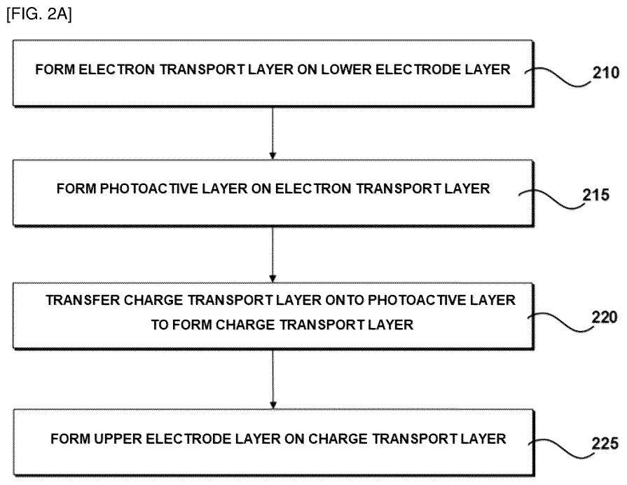

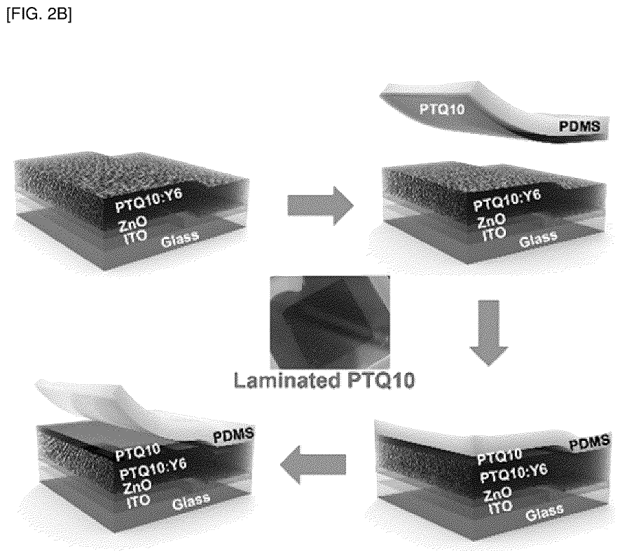

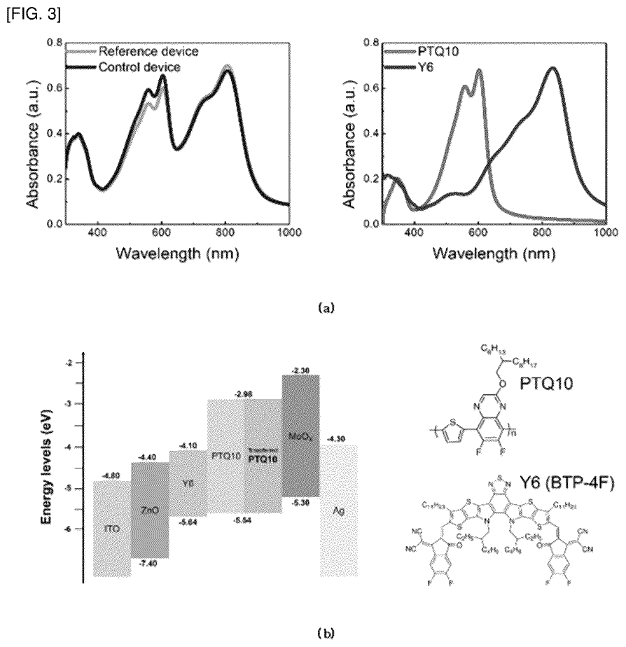

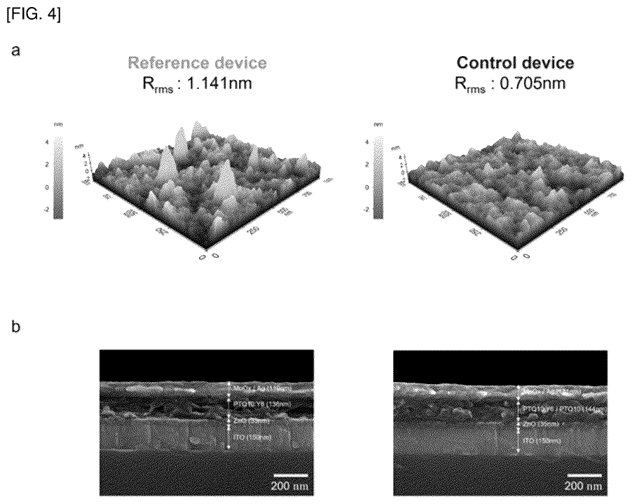

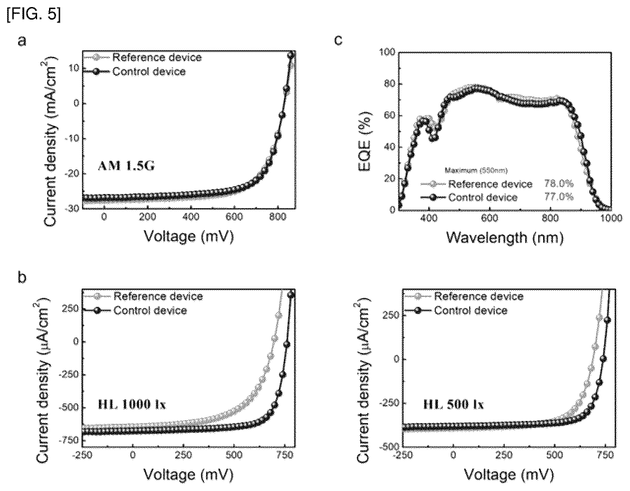

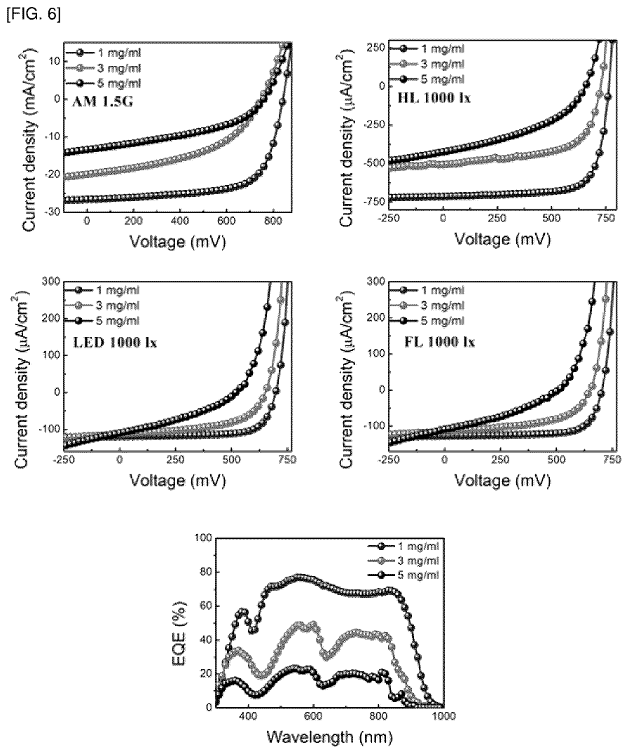

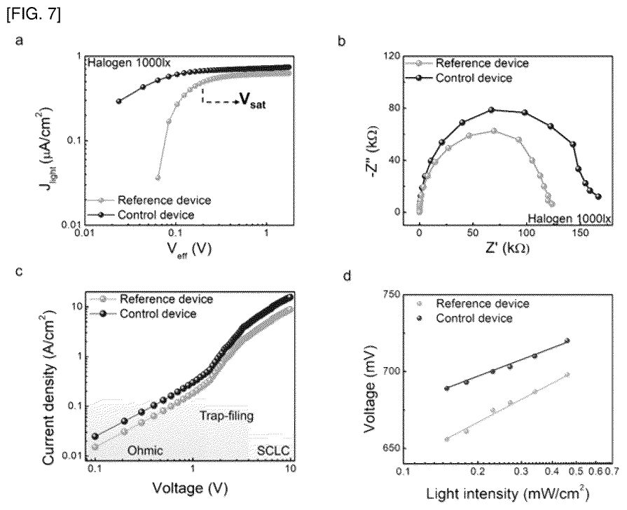

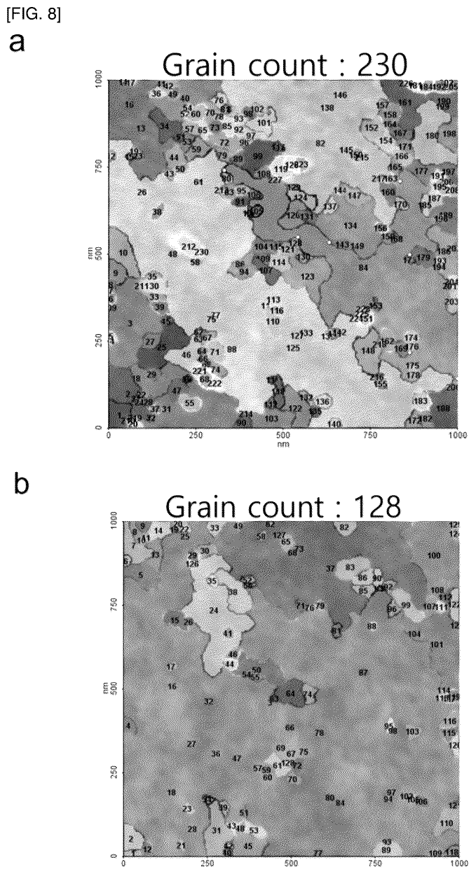

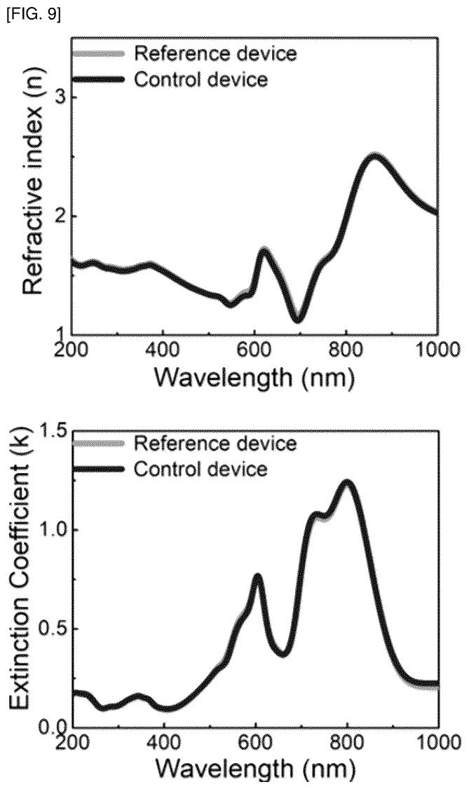

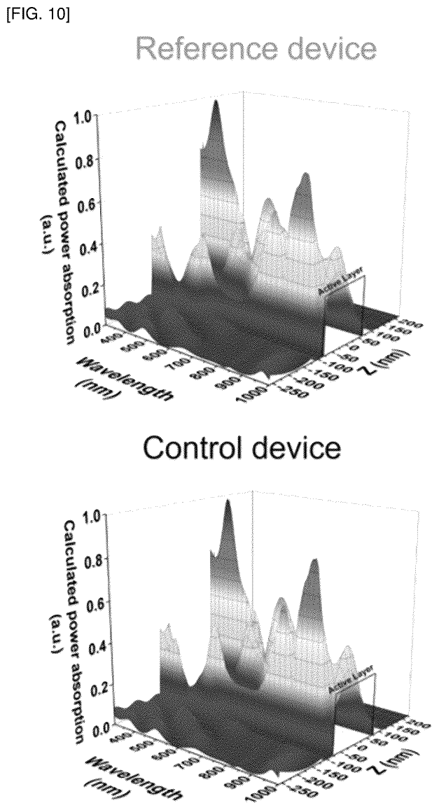

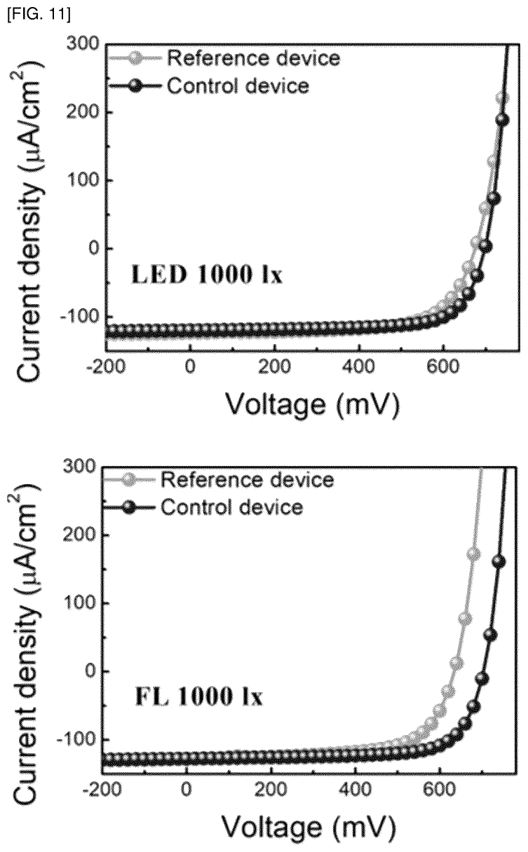

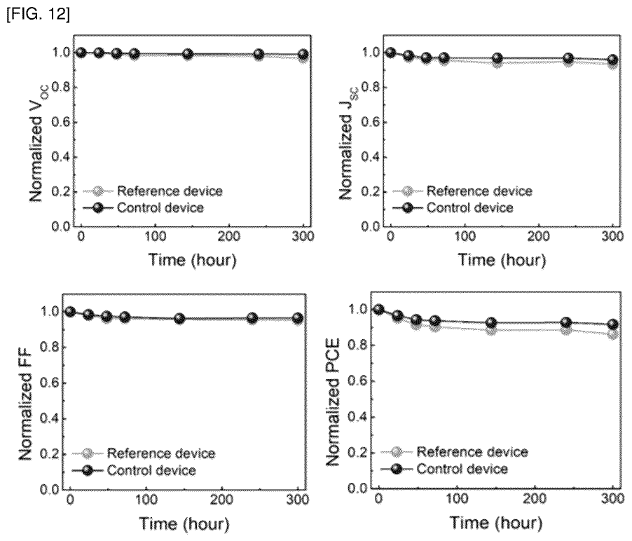

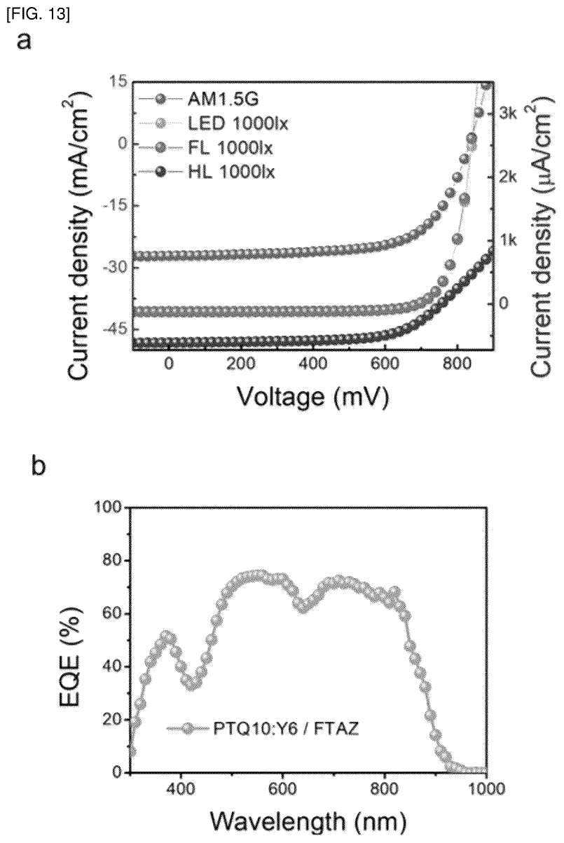

FIG. 1 is a diagram showing a detailed structure of an artificial indoor photovoltaic cell according to an embodiment of the present invention, FIGS. 2A and 2B are process diagrams showing a method of manufacturing artificial indoor photovoltaic cells according to an embodiment of the present invention, FIG. 3 is a diagram for describing a change in absorption spectrum and a chemical structure of an artificial indoor photovoltaic cell according to the related art and an embodiment of the present invention, FIG. 4 is a diagram showing a change in a thickness of a photoactive layer and a 3D AFM profile of the artificial indoor photovoltaic cell according to the related art and an embodiment of the present invention, FIG. 5 is a diagram showing a comparison result of J-V characteristics and EQE spectra of the artificial indoor photovoltaic cell according to the related art and an embodiment of the present invention, FIG. 6 is a diagram for describing photovoltaic cell performance according to a thickness according to an embodiment of the present invention, FIG. 7 is a comparison diagram of slope values for J_{light}-V_{eff} dependence, a Nyquist plot, a J-V curve, and VOC dependence for In(I_{light}) of the artificial indoor photovoltaic cell according to the related art and an embodiment of the present invention, FIG. 8 is a diagram showing 2D AFM grain-count of the artificial indoor photovoltaic cells according to the related art and an embodiment of the present invention, FIG. 9 is a comparison diagram of a complex refractive index of a photoactive layer according to the related art and an embodiment of the present invention, FIG. 10 is a diagram showing a power absorption rate of the artificial indoor photovoltaic cell according to the related art and an embodiment of the present invention, FIG. 11 is a diagram showing a comparison result of performance in indoor lighting of the artificial indoor photovoltaic cell according to an embodiment of the present invention, FIG. 12 is a diagram showing a comparison result of ambient safety of the artificial indoor photovoltaic cell according to the related art and an embodiment of the present invention, and FIG. 13 is a diagram showing performance and EQE spectrum of an FTAZ-based artificial indoor photovoltaic cell according to an embodiment of the present invention.

Referring to FIG. 1, an artificial indoor photovoltaic cell 100 according to an embodiment of the present invention is configured to include a substrate 110, a lower electrode layer 120, an electron transport layer 130, a photoactive layer 140, and a charge transport layer 150.

The substrate 110 is made of a material that is transparent and transmits light. The substrate 110 is formed of a glass material, but is not necessarily limited to glass.

The lower electrode layer 120 is formed on the transparent substrate 110 and may transmit light and allow current to flow. For example, the lower electrode layer 120 may be made of indium tin oxide (ITO). The lower electrode layer 120 may not necessarily be limited to ITO.

The electron transport layer 130 is a layer through which electrons move and may be formed on the lower electrode layer 120. The electron transport layer 130 may serve to transport electrons separated from the photoactive layer 140 to the lower electrode layer 120. The electron transport layer 130 may be made of zinc oxide (ZnO).

The photoactive layer 140 is formed on the electron transport layer 130. The photoactive layer 140 may include a donor layer and an acceptor layer that are made of at least two or more organic polymer materials, form excitons by indoor light, and separate the excitons into positive and negative charges.

For example, the donor layer may be formed of at least one of PTQ10, PM6 (PBDB-T-2F), PM7 (PBDB-T-2Cl), and PEDOT, and the acceptor layer may be formed of at least one of Y6, PC71BM, and PSS.

In an embodiment of the present invention, for convenience of understanding and description, it is assumed that the donor layer is formed of PTQ10 and the acceptor layer is formed of Y6, which will be mainly described.

The electron transport layer 130 is formed on the photoactive layer 140. The electron transport layer 130 may be made of a material homogeneous with a material forming the photoactive layer 140. More specifically, the electron transport layer 130 may be formed on the photoactive layer 140 by a transfer lamination technique after a solution process of a material homogeneous with the donor layer.

For example, when the donor layer is formed of PTQ10, a hole transport layer may be formed of PTQ10. In this case, the homogeneous PTQ10 used for the donor layer may be temporarily solution-processed on silicon-based organic polymer (hereinafter referred to as PDMS), and then physically transferred to the photoactive layer 140 to form the charge transport layer 150.

In an embodiment of the present invention, the charge transport layer may be formed by forming a transport layer to be transferred onto the PDMS by a solution process method, and transferring the transport layer onto the photoactive layer 140 in a downward direction without a separate heat treatment. In this way, since the PDMS is used, the charge transport layer may be formed without damage to the lower layer due to surface planarization and heat treatment.

Since an embodiment of the present invention assumes that the photoactive layer 140, that is, the donor layer is formed of PTQ10, it is assumed that the hole transport layer is formed of PTQ10 homogeneous with the donor layer. However, the hole transport layer may vary depending on the material forming the photoactive layer, and may be applied without limitation when formed of a material homogeneous with the photoactive layer.

A method of manufacturing an artificial indoor photovoltaic cell will be described in more detail with reference to FIGS. 2A and 2B.

In step 210, ZnO nanoparticles are spin-coated on the lower electrode layer 120 and then annealed at 200° C. for 1 hour using a 0.2 μm poly(tetrafluoroethylene) (PTFE) filter to form the electron transport layer 130.

Subsequently, in step 215, 16 mg/ml PTQLY6 (1:1.2) was dissolved in chloroform (1-chlorophthalene 0.5% additive) and stirred at 50° C. for 3 hours to form a photoactive layer, spin-coated on an ITO/ZnO film at 300 rpm for 30 seconds, and annealed at 90° C. for 10 minutes.

In step 220, PTQ10 (1 to 5 mg/ml) is coated on the PDMS through spin coating at 3000 rpm for 30 seconds and immediately transferred onto the photoactive layer 140 to form the charge transport layer 150.

Finally, in step 225, MoOX (10 nm) and Ag (150 nm) electrodes are deposited by thermal evaporation under a high pressure shadow mask of about 10 to 8 Pa.

In more detail, referring to FIG. 2B, in order to form the charge transport layer on the photoactive layer (PTQ10:Y6) 140, the PTQ10 homogeneous with the photoactive layer may be formed on the PDMS, and then, the corresponding PTQ10 coating layer may be positioned facing down so that it is positioned on the photoactive layer 140 and then transferred, thereby forming a PTQ10 charge transport layer 150 on the photoactive layer 140.

In order to confirm the presence of the charge transport layer 150 formed of the homogeneous PTQ10 between the photoactive layer and the positive electrode, the absorption spectrum of the PTQ10:Y6 photoactive layer and the double layer (PTQ10:Y6 and transfer-laminated PTQ10) was measured by UV-visible spectrometry. As shown in FIG. 3, the presence of an additional PTQ10 layer may be confirmed as a slightly increased absorption profile is observed in the double layer over the spectral range of 500 to 600 nm corresponding to the absorption range of the PTQ10.

FIG. 4 is a diagram showing a result of performing atomic force microscopy (AFM) to investigate the evolution of the surface morphology of the film regardless of whether the PTQ10 layer is laminated. An image having RMS surface roughness values determined based on an AFV height profile over an area of 1 μm² is shown in a of FIG. 4. A clear difference is observed between the RMS roughness values before and after the lamination of the additional PTQ10 layer, which clearly indicates the presence of the PTQ10 layer on the upper portion of the PTQ10:Y6 layer.

In addition, SEM images were acquired to confirm the presence of the PTQ10. a of FIG. 4 is a SEM image when the charge transport layer is not formed, and b of FIG. 4 is a SEM image when the charge transport layer is present. Hereinafter, the artificial indoor photovoltaic cell without the PTQ10 charge transport layer will be referred to as a reference device, and the artificial indoor photovoltaic cell including the PTQ10 charge transport layer will be collectively referred to as a control device for comparison. Even if there is no separate description below, the reference device should be interpreted as the conventional artificial indoor photovoltaic cell that does not include the PTQ10 charge transport layer, and the control device should be interpreted as the artificial indoor photovoltaic cell with the PTQ10 charge transport layer.

FIGS. 7 and a of 4 show top-down and cross-section profiles of the reference device and the control device. It was confirmed in FIG. 7 that the PTQ10 charge transport layer was successfully transferred to the photoactive layer. In addition, as shown in b of FIG. 4, it can be seen that the PTQ10 charge transport layer is transferred, and then the thickness of the photoactive layer increased from 136 nm to 144 nm to form the PTQ10 layer.

In addition, current density-voltage (J-V) characteristic curves of the artificial indoor photovoltaic cells with and without the PTQ10 layer were compared under various lighting conditions.

a and b of FIG. 5 are diagrams showing J-V curves under sun and indoor lighting (HL), respectively.

Solar parameters are shown in Table 1.

TABLE 1

| | | | J_{SC} | | |
|---|---|---|---|---|---|
| | | V_{OC} | (AM1.5G: mA/cm²) | FF | PCE |
| Light source | Structure | (mV) | (Indoor: μA/cm²) | (%) | (%) |
| AM1.5G | Reference | 830 ± 2 | 27.5 ± 0.2 | 65.5 ± 0.1 | 14.9 ± 0.1 |
| (100 mW/cm²) | device | | | | |
| | Control device | 828 ± 7 | 26.7 ± 0.2 | 69.6 ± 0.1 | 15.4 ± 0.1 |
| Halogen 500 lx | Reference | 688 ± 2 | 391.6 ± 0.6 | 66.8 ± 0.1 | 4.2 ± 0.1 |
| (4.2 mW/cm²) | device | | | | |
| | Control device | 739 ± 2 | 380.0 ± 1.0 | 73.7 ± 0.1 | 4.9 ± 0.1 |
| Halogen 1000 lx | Reference | 743 ± 1 | 667.7 ± 1.1 | 65.2 ± 0.9 | 4.6 ± 0.1 |
| (7.0 mW/cm²) | device | | | | |
| | Control device | 785 ± 8 | 685.2 ± 2.5 | 74.0 ± 0.8 | 5.7 ± 0.2 |

Under the sunlight lighting, when there was no PTQ10 charge transport layer and when there was a PTQ10 charge transport layer, similar photovoltaic cell performance was indicated.

Unlike the case without the PTQ charge transport layer, when the PTQ10 charge transport layer is present, the optimization was analyzed by changing the thickness of the PTQ10 charge transport layer. The thickness of the PTQ10 charge transport layer 150 was controlled by changing the concentration of the PTQ10 solution, and optimal performance was achieved in the PTQ10 charge transport layer having a thin thickness of about 8 nm using a 1 mg/ml solution.

As shown in FIG. 6, when the thickness of the resistive PTQ10 charge transport layer increases, the charge collection efficiency decreases to some extent, and thus the performance of the artificial indoor photovoltaic cell deteriorates.

In c of FIG. 5, a JSC value is confirmed by measuring external quantum efficiency (EQE) of the artificial indoor photovoltaic cell of the reference device and the control device. As shown in c of FIG. 5, no significant difference was observed between the EQE spectra according to the presence or absence of the PTQ10 charge transport layer, but it was consistent with the high similarity between the JSC values.

As shown in Table 1, the indoor performance of the artificial indoor photovoltaic cell according to the presence or absence of the PTQ10 charge transport layer is different. In the case of the artificial indoor photovoltaic cell without the PTQ10 charge transport layer under 1000-lx halogen illumination (IL: 7.0 mW/cm²), which is a typical indoor lighting, PCE=4.6±0.1% with V_{OC}=743±1 mV, J_{SC}=667.7±1.1 μA/cm², j, FF=65.2±0.9% are shown in Table 1.

However, in the case of the artificial indoor photovoltaic cell including the PTQ10 charge transport layer as in one embodiment of the present invention, it can be seen that V_{OC}=785±8 mV, J_{SC}=685.2±2.5 μA/cm², and FF=74.0±0.1%, which may show better performance. In particular, it can be seen that PCE=5.7±0.2% shows about 25% better performance compared to the reference device. It can be seen that the PCE value of the control unit corresponds to an output power density (Pmax) of ˜413 μW/cm², which is sufficient for low-power electronic devices.

That is, as shown in FIG. 5 and Table 1, it can be seen that all artificial indoor photovoltaic cell parameters are improved. In particular, FF was improved by about 13% or more. This shows positive effects (reduced defect density, reduced leakage current, etc.) on interfacial properties of the control device, which improves performance in indoor environments, and the transfer lamination method is effective in reducing defective alignment under low-illumination indoor lighting conditions.

In one embodiment of the present invention, the improvement of the FF value under the 1000-lx halogen illumination condition was analyzed using an equivalent circuit model. The equivalent circuit model may be expressed as Equation 1.

$$\{ \frac{{v}_{OC} - ln ( {v}_{OC} + 0.72}{( {v}_{OC} + 1 )} \} ( 1 - 1.1 {r}_{5} ) + 0.19 {r}_{s}^{2} \{ 1 - \frac{( {v}_{OC} + 0.7}{{v}_{OC}} \frac{\frac{( {v}_{OC} - ln ( {v}_{OC} + 0.72 )}{( {v}_{OC} + 1 )} ( 1 - 1.1 {r}_{s} ) + 0.19 {r}_{s}^{2}}{{r}_{p}} \} ; \qquad [ Equation 1 ]$$

$$( 0 \leq {r}_{s} + \frac{1}{{r}_{p}} \leq 0.4 )$$

Equation 1 is an expression derived from an equivalent circuit describing a parasitic resistance effect on FF.

A significantly high RP value (RP=3.3×10⁵ Ω·cm² of the reference device and RP=5.0×10⁵ Ω·cm² of the control device) was extracted from the J-V characteristics, and in the case of the control device, it can be seen that the performance improvement of the FF value was about 51% or more.

On the other hand, similar and small rs values were recorded as 3.2×10³ Ω·cm² and 3.1×10³ Ω·cm² for the reference device and control device, respectively.

In addition, the R_{CH} values calculated based on the V_{OC} and J_{SC} under the 1000-lx halogen lighting conditions were also similar as 2.4×10⁴ Ω and 2.5×10⁴ Ω for the reference device and control device, respectively.

As described above, it can be seen based on the parasitic resistance value, the R_{CH} value, and the similar and small rs value that the performance difference between the reference device and the control device depends on the Rₚ value. That is, it can be seen that FF greatly depends on Rₚ.

To further confirm the Rp-related FF performance enhancement, the charge transport and collection were characterized by evaluating light-induced current density J_{light} as a function of effective voltage V_{eff}. Here, J_{light} represents the difference between the current densities under the lighting condition and the dark state, and V_{eff} represents the difference between the applied voltage and the voltage at Jₚₕ=0.

a of FIG. 7 is a diagram showing the J_{light}-V_{eff} dependence of the reference device and the control device in the 1000-lx halogen lighting. It can be seen that the artificial indoor photovoltaic cell according to an embodiment of the present invention exhibits relatively fast J_{light} saturation at V_{eff}=0.281V, and the reference device exhibits corresponding J_{light} saturation at V_{eff}=0.413V.

The difference between the Veff values of the reference device and the control device reflects the relatively low electric field dependence of the artificial indoor photovoltaic cell having the PTQ10 charge transport layer according to an embodiment of the present invention. Therefore, it can be seen that the artificial indoor photovoltaic cell having the PTQ10 charge transport layer according to an embodiment of the present invention is capable of transporting and collecting excellent charge having a lower trapped charge density and has a higher FF value.

J_{light} saturation mainly depends on a maximum excitation generation rate Gₘₐₓ, which may be expressed as in Equation 2.

$${G}_{max} = \frac{{J}_{sat}}{qL} \qquad [ Equation 2 ]$$

In Equation 2, Jₛₐₜ is obtained by multiplying q, L, and Gₘₐₓ, q denotes a basic charge number, L denotes the thickness of the photoactive layer, and the Gₘₐₓ value calculated based on Jₛₐₜ is 2.88×10²⁸ m⁻³s⁻¹ in the case of the conventional artificial indoor photovoltaic cell (i.e., not including the PTQ10 charge transport layer), and is 2.97×10²⁸ m⁻³s⁻¹ in the case of an artificial indoor photovoltaic cell having the PTQ10 charge transport layer according to an embodiment of the present invention. Despite the similar Gₘₐₓ value, the improved FF value of the artificial indoor photovoltaic cell according to an embodiment of the present invention means that the artificial indoor photovoltaic cell according to an embodiment of the present invention has excellent charge transfer characteristics while reducing charge recombination.

In addition, charge dynamics were analyzed using electrochemical impedance spectroscopy (EIS). The EIS measurement of the artificial indoor photovoltaic cell according to the related art and an embodiment of the present invention was performed at 0.6V under the 1000-lx halogen condition. b of FIG. 7 shows a Nyquist plot of the artificial indoor photovoltaic cell according to the related art and an embodiment of the present invention. A recombination resistance R_{rec} according to a semicircle diameter of a plot was shown as 92.54 kΩ and 134.06 kΩ, respectively, for the artificial indoor photovoltaic cell according to the related art and an embodiment of the present invention. The large R_{rec} value of the artificial indoor photovoltaic cell according to an embodiment of the present invention represents the suppressed charge recombination characteristics, which coincides with the large Rₚ value.

Additionally, space-charge-limited current (SCLC) measurement was used to obtain additional information on hole trap density. To this end, a dedicated hall device with a structure of ITO/poly(3,4-ethylenedioxythiophene): poly(styrene sulfonate)/PTQ10: Y6 or PTQ10: Y6/PTQ10/MoOX/Ag was manufactured.

c of FIG. 7 shows a J-V curve of the artificial indoor photovoltaic cell. Ohmic conduction corresponding to a low voltage (i.e., 0.1V<V<1.5V) was observed with m=1 for both devices. A current increases rapidly in both devices in response to an intermediate voltage (1.5V<V<3V), and thus, the trap charging occurrence appears. The charge traps distributed in energy may be filled by gradually increasing the electric field. A limit voltage V_{TFL} with which the 3Vdml trap is filled follows Mott's V² law without traps, and the trap density may be estimated using Equation 3.

$${V}_{TFL} = \frac{{eN}_{t} {d}^{2}}{2 {ε}_{r} {ε}_{0}} \qquad [ Equation 3 ]$$

V_{TFL} denotes a starting voltage of a limit region in which the trap was filled, L denotes the thickness of the photoactive layer, εr denotes a relative permittivity, and ε₀ denotes a vacuum permittivity (8.854×10⁻¹² F·m⁻¹).

Here, it is assumed that both the photoactive layer (PTQ10:Y6) and the photoactive layer/charge transport layer (PTQ10:Y6/PTQ10) are εr=4. A slightly smaller V_{TFL} was observed in the artificial indoor photovoltaic cell with the PTQ10:Y6/PTQ10 layer, which refers to a lower hole trap density in the artificial indoor photovoltaic cell with the PTQ10 charge transport layer.

The calculated hole trap density of the device (4.26×10¹⁷ cm⁻³) according to an embodiment of the present invention was lower than that of the reference device (6.69×10¹⁷ cm⁻³), which indicates that the integration of the homojunction charge transport layer reduces the trap density.

An in-depth analysis of the AFM image was performed to determine the effect of morphological changes induced by the integration of the charge transport layer on the FF.

As described above, the introduction of the PTQ10 charge transport layer further flattened the surface of the PTQ10:Y6 photoactive layer. The smoother the surface, the better charge transfer is promoted. In this regard, a smooth surface of the PTQ10:Y6 photoactive layer/PTQ10 charge transport layer (RMS roughness=0.705 nm) is activated compared to the PTQ10:Y6 photoactive layer (RMS roughness=1.141 nm). More efficient charge transport leads to higher FF values. Also, when the PTQ10 charge transport layer was added, the number of particles was noticeably changed. FIG. 8 shows each grain number obtained using the corresponding grain mapping of the PTQ10:Y6 and PTQ10:Y6/PTQ10 layers and a watershed algorithm. Each of the PTQ10:Y6 and PTQ10:Y6/PTQ10 layers showed the number of particles of 160 (25 μm²) and 121 (25 μm²). In general, a larger number of particles (i.e., smaller particle size) indicate the presence of more grain boundaries that reflect the generation of a larger number of trap sites. These sites impede charge transport and create charge recombination centers, greatly degrading the FF. Therefore, the decrease in the FF of the conventional artificial indoor photovoltaic cell including only the PTQ10:Y6 photoactive layer may be partially due to the increase in the number of particles.

In addition, the increased V_{OC} value of the artificial indoor photovoltaic cell having the PTQ10 charge transport layer may be attributed to some extent to the higher degree of splitting of the quasi-Fermi level due to the homogeneity of the PTQ10 charge transport layer. When the difference between the WFs of the charge collection intermediate layers on both sides of the photoactive layer is sufficiently large, the V_{OC} is limited by the energy gap between the ionization potential of the donor and the electron affinity of the acceptor. The PTQ10 charge transport layer exhibited a donor-dominant region generating the quasi-Fermi level maximized on the donor side of the photoactive layer. Potential losses associated with the presence of counterparts in heterojunction may be recovered by integrating the homojunction charge transport layer.

The effect of suppressing charge recombination on V_{OC} evolution will be analyzed.

$${V}_{OC} = \frac{kT}{q} ln \{ 1 + \frac{{J}_{ph}}{{J}_{0}} ( 1 - \frac{{V}_{OC}}{{J}_{ph} {R}_{p} A} ) \} \approx \frac{kT}{q} ln \{ 1 + \frac{{J}_{ph}}{{J}_{0}} \} \qquad [ Equation 4 ]$$

Equation 4 represents the V_{OC} of the artificial indoor photovoltaic cell when only bimolecular recombination is considered.

$${V}_{OC} = \frac{{E}_{gqp}}{q} - \frac{kT}{q} ln \{ \frac{( 1 - {P}_{D} ) γ {N}_{C}^{2}}{{P}_{D} G} \} \qquad [ Equation 5 ]$$

Equation 5 represents V_{OC} with only one parameter, C, which is directly proportional to lighting. The ratio between V_{OC} and In(I_{light}) provides the analysis of the contribution of additional surface recombination. In general, when the bimolecular recombination is the main loss mechanism in the artificial indoor photovoltaic cell, the slope of the VOC dependence curve for In(I_{light}) is 1. A slope higher than 1 reflects competition between the trap-assisted recombination and t bimolecular recombination. In this case, the V_{OC} may vary mainly in response to the lighting intensity. d of FIG. 7 shows a slope value for the V_{OC} dependence on the In(I_{light}) of the artificial indoor photovoltaic cells according to the embodiment of the related art and the present invention under the indoor lighting conditions.

It can be seen that the slope (1.063) of the artificial indoor photovoltaic cell according to an embodiment of the present invention is closer to 1 than that of the reference device (1.354). According to Equation 4, it can be seen that the artificial indoor photovoltaic cell having the PTQ10 charge transport layer has a low trap-assisted recombination loss and a negligible potential loss. This is consistent with the increase in Rₚ by the PTQ10 charge transport layer, and it can be seen that the PTQ10 charge transport layer has a direct effect on the performance improvement of the artificial indoor photovoltaic cell having the PTQ10 charge transport layer. Under the 1000-lx halogen lighting, the J_{SC} value was not significantly affected by the change in parasitic resistance, and the light absorption power was more important in determining the J_{SC}.

$${J}_{SC} = - \frac{1}{1 + \frac{{R}_{s}}{{R}_{p}}} [ {J}_{ph} - {J}_{0} \{ exp ( \frac{\vert {J}_{SC} \vert {R}_{s} A}{\frac{nkT}{e}} ) - 1 \} ] \qquad [ Equation 6 ]$$

In Equation 6, a first term

$$\frac{1}{( 1 + \frac{{R}_{s}}{{R}_{p}} )}$$

may be partially determined by the ratio of RₛA to RₚA. In both the artificial indoor photovoltaic cells according to the rated art and an embodiment of the present invention, since a RₛA value (reference device=144.9 Ω·cm², control device=139.5 Ω·cm²) is appropriately small and a RₚA value (reference device=1.5 104 Ω·cm², control device=2.3 104 Ω·cm²) is large, the Rₛ/Rₚ value (conventional device=0.009, control device=0.006) may be concluded to be similar based on Equation 6. Therefore, no dependence of J_{sc} on parasitic resistance is expected. Finite-difference time-domain (FDTD) simulations were performed to estimate the light absorption. The complex refractive index of the photoactive layer will be referred to FIG. 9. FIG. 10 and Table 2 show power absorption rates of the reference and control devices obtained through the FDTD simulation.

TABLE 2

J_{oh.Ideal}

| | HL 500 lx | HL 1000 lx |
|---|---|---|
| Sample name | (μA/cm²) | (μA/cm²) |
| Reference | 659.114 | 973.944 |
| device | | |
| Control device | 647.352 | 956.809 |

The 3D image mapping represents the normalized value of the integrated power absorption ratio. It can be seen that the simulated J_{SC} value showed no noticeable change after adding the PTQ10 charge absorbing layer and was in agreement with the measured J_{SC} value. The discrepancy between the measured J_{SC} value and the simulated J_{SC} value may be due to the FDTD simulation. Only the optical properties were considered here, and the electrical resistance was excluded.

It can be seen that the reference and control devices exhibit similar performance evolution trends for different 1000-lx LED lamps and 1000-lx FL. The increase in the FF and V_{OC} combined with the comparable J_{SC} values led to the improved performance of the control unit compared to the reference device. As a result, the PCE values of the control device increased by up to 26.4±0.1% and 23.9±0.6% under the LED and FL conditions, respectively. Details of the photovoltaic cell parameters are shown in FIG. 11 and Table 3.

TABLE 3

| | | V_{OC} | J_{SC} | FF | PCE |
|---|---|---|---|---|---|
| Light source | Structure | (mV) | (μA/cm²) | (%) | (%) |
| LED 1000 lx | Reference | 675 ± 2 | 123.4 ± 0.1 | 68.3 ± 0.3 | 23.7 ± 0.1 |
| (0.23 mW/ | device | | | | |
| cm²) | Control | 698 ± 2 | 119.5 ± 0.3 | 72.8 ± 0.1 | 26.4 ± 0.1 |
| | device | | | | |
| FL 1000 lx | Reference | 680 ± 2 | 124.2 ± 2.0 | 67.5 ± 0.4 | 21.1 ± 0.4 |
| (0.27 mW/ | device | | | | |
| cm²) | Control | 703 ± 2 | 126.0 ± 3.1 | 72.9 ± 0.3 | 23.9 ± 0.6 |
| | device | | | | |

The comparison results of ambient stability between the reference device and the control device are shown in FIG. 12. It can be seen that slightly better stability is observed in the control device. Both the reference and control devices did not show the severe performance degradation when exposed to ambient air for more than 300 hours.

The results of applying another polymer donor (fluorobenzotriazole (FTAZ)) for universal applicability of the lamination technology are shown in FIG. 13 and Table 4.

TABLE 4

| | | J_{SC} | | |
|---|---|---|---|---|
| | V_{OC} | (AM1.5G: mA/cm²) | FF | PCE |
| Light source | (mV) | (Indoor: μA/cm²) | (%) | (%) |
| AM1.5G | 833 ± 2 | 27.1 ± 0.1 | 66.6 ± 0.2 | 15.0 ± 0.1 |
| (100 mW/cm²) | | | | |
| LED 1000 lx | 688 ± 4 | 120.7 ± 4.3 | 69.0 ± 0.8 | 24.9 ± 0.3 |
| (0.23 mW/cm²) | | | | |
| FL 1000 lx | 692 ± 2 | 125.4 ± 2.2 | 68.5 ± 0.9 | 22.0 ± 0.2 |
| (0.27 mW/cm²) | | | | |
| HL 1000 lx | 756 ± 3 | 650.5 ± 15.4 | 67.6 ± 0.1 | 4.7 ± 0.1 |
| (7.0 mW/cm²) | | | | |

Similar to the case where the PTQ10 charge transport layer was laminated using the homogenous transfer technique, even when the fluorobenzotriazole (FTAZ) was applied as the homogenous transfer technique, it can be seen that the significant improvement in photovoltaic cell performance is shown as in the PTQ10 charge transport layer.

Hereinabove, the present invention has been described with reference to exemplary embodiments thereof. It will be understood by those skilled in the art to which the present invention pertains that the present invention may be implemented in a modified form without departing from essential characteristics of the present invention. Therefore, the exemplary embodiments disclosed herein should be considered in an illustrative aspect rather than a restrictive aspect. The scope of the present invention should be defined by the claims rather than the above-mentioned description, and all differences within the equivalents to the claims should be interpreted to fall within the present invention.

What is claimed is:

1. An artificial indoor photovoltaic cell, comprising:
a transparent electrode;
an electron transport layer formed on the transparent electrode layer;
a photoactive layer formed on the electron transport layer and including a donor layer and an acceptor layer that generate an exciton by indoor light and separate the exciton into positive and negative charges; and
a charge transport layer formed on the photoactive layer and made of a material homogenous with the donor layer.

2. The artificial indoor photovoltaic cell of claim 1, wherein the charge transport layer is formed by a lamination technique of forming a coating layer on one surface of a silicon-based organic polymer (PDMS) using a material homogeneous with the donor layer through a solution process method, and transferring the coating layer onto the photoactive layer.

3. The artificial indoor photovoltaic cell of claim 1, wherein the donor layer and the charge transport layer are made of any one polymer material among PTQ10, PM6 (PBDB-T-2F), PM7 (PBDB-T-2Cl), PEDOT, and fluorobenzotriazole (FTAZ), respectively.

4. The artificial indoor photovoltaic cell of claim 1, wherein the charge transport layer is formed to have a thickness of 1 to 8 nm or less.

5. A method of manufacturing an artificial indoor photovoltaic cell, comprising:
forming an electron transport layer on a transparent electrode layer;
forming a photoactive layer including a donor layer and an acceptor layer, which generate an exciton by indoor light and separate the exciton into positive and negative charges, on the electron transport layer; and
forming a charge transport layer made of a homogeneous material with the donor layer on the photoactive layer.

6. The method of claim 5, wherein the forming of the charge transport layer comprises:
forming a coating layer by coating one surface of a silicon-based organic polymer (PDMS) with a material homogeneous with the donor layer; and
forming the charge transport layer on the photoactive layer by a lamination technique of disposing the coating layer on an upper surface of the photoactive layer and then transferring the coating layer onto the photoactive layer.

7. The method of claim 5, wherein the donor layer and the charge transport layer are made of any one polymer material among PTQ10, PM6 (PBDB-T-2F), PM7 (PBDB-T-2Cl), PEDOT, and fluorobenzotriazole (FTAZ), respectively.
